(19) United States
(12) Patent Application Publication
(10) Pub. No.: US 2005/0167370 A1
(43) Pub. Date: Aug. 4, 2005

(54) Resin microchannel substrate and method of manufacturing the same

(75) Inventors: Mitsutoshi Nakajima, Tsukuba-shi (JP); Yuji Kikuchi, Tsukuba-shi (JP); Taiji Nishi, Tsukuba-shi (JP); Takenori Kitani, Tsukuba-shi (JP); Yukihiro Yanagawa, Kashima-gun (JP); Motohiro Fukuda, Tsukuba-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: National Food Research Institute, Tsukuba-shi (JP); KURARAY CO. LTD., Kurashiki-shi (JP)

(21) Appl. No.: 10/814,177

(22) Filed: Apr. 1, 2004

(30) Foreign Application Priority Data
Feb. 2, 2004 (JP) 2004-025039

(51) Int. Cl. B01D 37/00; H01L 21/302; H01L 21/461

(52) U.S. Cl. 210/767; 438/689

(57) ABSTRACT

The resin microchannel substrate has a surface where a recess leading to a fluid supply port and a bank adjacent to the recess and having many micro grooves on a surface are formed. The grooves form microchannels connecting the inside of the recess and the outside of the recess when the surface of the substrate is firmly attached to a flat plate serving as a cover. The width and height of the microchannel are within a range of 1 to 300 μm, and the width/height ratio of the channel is within a range of 1:20 to 20:1.

### BACKGROUND OF THE INVENTION

1. Field of the Invention

The present invention relates to a resin microchannel substrate suitable for filtration and classification or production of an emulsion, a method of manufacturing the resin microchannel substrate, a method of filtration and classification, and a method of producing an emulsion.

2. Description of the Related Art

Filers such as Millipore and Nuclepore filters are used for filtration and classification of particles or production of an emulsion. However, since the pore shape and size of these filters are not uniform, their performances such as separation capability or uniformity of the particle size of a produced emulsion are insufficient. Further, since a filtration and classification process or an emulsion production process cannot be observed directly, filter performance degradation such as pore blocking or narrowing is detected only indirectly by increase in pressure drop or change in product size.

To eliminate the above problems, it has been proposed to produce a microchannel substrate by semiconductor microfabrication technique, which patterns a silicon substrate by photolithography and micro-fabricates a groove on the silicon substrate by wet or dry etching, and use the microchannel substrate for the filtration and classification or the production of an emulsion.

This technique equalizes the shape and size of microchannels and allows direct observation of the actual flow in the channel through a transparent plate. Further, it enables the design of the diameter/length ratio, interval, port shape, and so on of the microchannels in accordance with the purposes.

It has been proposed to increase the processable amount at one time while maintaining the advantages of the shape and size uniformity and the direct observability of the microchannels so as to enhance practicality. In order to increase the number of microchannels, in which a laminated microchannel array device, a plurality of substrates are placed on one another in the same direction and in close contact with one another to form many microchannels on a contact surface, has been developed. This technique is disclosed in Japanese Unexamined Patent Application Publication H11-165062, for example.

However, the semiconductor microfabrication technique that micro-fabricates a groove on a silicon substrate by wet or dry etching has practical problems such as: (1) high material cost of the silicon substrate, (2) high processing cost due to the photolithography performed for each and every substrate, (3) varying dimensional accuracy of each microchannel, and (4) low alkali resistance.

### SUMMARY OF THE INVENTION

An object of the present invention is to provide a resin microchannel substrate suitable for filtration and classification or production of an emulsion, a method of manufacturing the resin microchannel substrate, a method of filtration and classification, and a method of producing an emulsion.

According to the present invention, for achieving the above-mentioned object, there is provided a resin microchannel substrate including a surface having a recess leading to a fluid supply port and a bank adjacent to the recess and having many micro grooves on a surface, which grooves form microchannels connecting an inside of the recess and an outside of the recess when the surface of the substrate is firmly attached to a flat plate serving as a cover, wherein each of width and height of the microchannels is within a range of 1 to 300 μm and a width/height ratio of the microchannels is within a range of 1:20 to 20:1.

In the resin microchannel substrate, a contact angle of the surface of the resin microchannel substrate with respect to water is preferably 5° to 60°. The resin microchannel substrate according to this invention is suitable for the production of monodispersed oil-in-water microparticles.

Further, in the resin microchannel substrate, an edge angle of the many grooves on the surface of the bank may be 90° or less, or the many grooves on the surface of the bank may have a fine raised and recessed structure. This allows the production of an emulsion with a uniform particle size

According to the present invention, it is able to provide a resin microchannel substrate suitable for filtration and classification or production of an emulsion, a method of manufacturing the resin microchannel substrate, a method of filtration and classification, and a method of producing an emulsion.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIGS. 1A to 1H are pattern diagrams showing a process of manufacturing a resin microchannel substrate according to the present invention.

FIG. 2 is an outline view of a resin microchannel substrate manufactured by the process shown in FIGS. 1A to 1H.

FIGS. 3A, 3B, and 3C are views showing the structure of a groove formed on a bank of a resin microchannel substrate manufactured by the process shown in FIGS. 1A to 1H.

FIGS. 4A, 4B, and 4C are views showing the structure of a groove formed on a bank of a resin microchannel substrate manufactured by the process shown in FIGS. 1A to 1H.

FIGS. 5A, 5B, and 5C are views showing the structure of a groove formed on a bank of a resin microchannel substrate manufactured by the process shown in FIGS. 1A to 1H.

FIGS. 6A, 6B, and 6C are views showing the structure of a groove formed on a bank of a resin microchannel substrate manufactured by the process shown in FIGS. 1A to 1H.

FIG. 7 shows an image observed optically with a CCD camera in an example.

FIG. 8 shows an image observed optically with a CCD camera in an example.

FIG. 9 shows an image observed optically with a CCD camera in an example.

FIG. 10 shows an example of a resin microchannel substrate.

### DESCRIPTION OF THE DRAWINGS

The present invention will be explained hereinafter in detail.

A method of producing an emulsion according to the present invention uses a resin microchannel substrate having a recess leading to a fluid supply port and a bank adjacent to the recess and having many micro grooves on the surface, which grooves form microchannels leading through the inside of the recess and the outside of the recess when the surface of the substrate is firmly attached to a flat plate as a cover, and sends a first fluid from the inside of the recess to the outside of the recess to disperse the first fluid in a second fluid supplied to the outside of the recess and not mixing with the first fluid.

By firmly attaching the surface of the substrate to a transparent flat plate as a cover, it is able to produce an emulsion while optically observing the emulsion production process in at least part of the channels through the transparent flat plate. It allows appropriate control of the emulsion production. Similarly, performing filtration and classification with the microchannel substrate while optically observing the process allows appropriate control of the filtration and classification.

The filters such as Millipore and Nuclepore filters used for the filtration and classification of particles or the production of an emulsion have insufficient performance of the separation capability, the uniformity of the particle size of produced emulsions, and so on due to nonuniform pore shape and size. On the other hand, a resin microchannel substrate produced by a molding method using a stamper, which allows reproducing a bank having many micro grooves with high accuracy and low cost, can achieve sufficient performance of the separation capability, the uniformity of produced emulsions, and so on.

When dispersing the first fluid through the channel in the second fluid supplied to the outside of the recess and not mixing with the first fluid, the uniformity of an emulsion particle size is determined by difference in the wettability of the first liquid and the resin microchannel substrate.

In the production of monodispersed water-in-oil microparticles, the first fluid is water and the second fluid is oil. In this case, to obtain a uniform emulsion particle size, it is required that the contact angle of the resin microchannel substrate surface with respect to water is large. If poly(methyl methacrylate) is used as a material of the resin microchannel substrate, for example, the contact angle of the substrate surface with respect to water is 68°, and it is easy to achieve a uniform emulsion particle size by the difference in wettability of water and the resin microchannel substrate. Similarly, if other thermoplastic resin is used as a material of the resin microchannel substrate, the difference in wettability of water and the resin microchannel substrate is large, and it is thus possible to obtain the monodispersed water-in-oil microparticles with a uniform particle size.

In the production of monodispersed oil-in-water microparticles, the first fluid is oil and the second fluid is water. In this case, to obtain a uniform emulsion particle size, it is required that the contact angle of the resin microchannel substrate surface with respect to water is small. Generally-used thermoplastic resin such as poly(methyl methacrylate) normally has a relatively large contact angle with respect to water (for example, about 68° with poly(methyl methacrylate) resin, about 70° with polycarbonate resin, and 84° with polystyrene resin). Thus, it is necessary to reduce the contact angle to the range from 5° to 60°.

Techniques to modify the wettability of a plastic surface are classified broadly into chemical treatment techniques and physical treatment techniques. The chemical treatment techniques include chemical treatment, solvent treatment, coupling agent treatment, monomer coating, polymer coating, steam treatment, surface grafting, electrochemical treatment, and so on. The physical treatment techniques include ultraviolet irradiation treatment, plasma contact treatment, plasma jet treatment, plasma polymerization treatment, ion beam treatment, mechanical treatment, and so on.

Some of the above modification techniques develop adhesive properties in addition to hydrophilic properties of the thermoplastic resin surface. Since it may be unfavorable for keeping many micro groove patterns of the resin microchannel substrate, a selection of the modification technique in accordance with a required contact angle is needed.

Further, if the plasma treatment, particularly sputtering, is selected from the physical treatment techniques, the heat-resistance temperature of 60° C. to 110° C. is required. Thus, it is important to select the conditions such as: (1) selecting polycarbonate and so on having the glass transfer temperature of higher than above temperature, and (2) reducing a sputtering time (reducing a film thickness).

To make the thermoplastic resin hydrophilic, a technique that requires a low heat-resistance temperature and is applicable to poly(methyl methacrylate) with the glass transfer temperature of 100° C. is the UV treatment, particularly excimer UV treatment. The excimer UV treatment uses an excimer lamp using discharge gas such as argon, krypton, and xenon for irradiation of ultraviolet light with the center emission wavelength of 120 nm to 310 nm. By the irradiation of the high energy ultraviolet light, the molecules on the resin surface dissociates and a light hydrogen atom is easily drawn to create a hydrophilic functional group such as OH, thereby increasing the wettability of the surface. Since this technique increases not only hydrophilic properties but also adhesive properties as the amount of UV exposure increases, which is sometimes unfavorable for keeping many micro groove patterns, it is necessary to select the amount of exposure in accordance with a required contact angle.

In the production of the monodispersed oil-in-water microparticles, to obtain an emulsion with a uniform particle size, the contact angle of the resin microchannel substrate surface with respect to water is preferably from 5° to 60°, and more preferably from 10° to 50°. If the contact angle is not in this range, the oil does not isolate after passing through the microchannel due to the wetting of the resin microchannel substrate surface and the oil as dispersed phase, which makes it unable to obtain an emulsion with a uniform particle diameter. It is thus preferable to have the contact angle within the above range in order to produce the emulsion with a uniform particle diameter and maximize its usability.

The particle diameter of a produced emulsion depends also on the size of the microchannel. To obtain a large particle diameter, it is needed to increase the channel width and depth. To obtain a small particle diameter, on the other hand, it is needed to decrease the channel width and depth. It is thus necessary to set the microchannel size in accordance with the required particle diameter. The molding method using the stamper is preferable since it can manufacture a large amount of accurate resin microchannel substrates at low cost by making stampers with different sizes in accordance with required particle diameters.

As for a minimum size of the channel to be formed, it is possible to form the channel with the width of as small as 1 μm or less by using a scale-down exposure device called a stepper in the exposure step during the stamper manufacturing process, for example. However, since it requires an expensive mask for the exposure, it is preferred to select it considering production costs and intended uses.

The length of the channel is preferably determined in accordance with the viscosity of the phase used as dispersed phase. If the channel is too long, high pressure is required to transmit high-viscosity material. If, on the contrary, the channel is too short, it would be difficult to control the transmission speed since a transmission pressure is low. It is thus preferred to select the channel length in accordance with the viscosity of a material used.

As for edge shapes of many grooves formed on the surface of the bank, it is preferred that the shape in the depth direction is most possibly equal to a rectangle, and the edge angle viewed from above is 90° or less. In order for the dispersed phase to pass through the channel and disperses with a uniform particle diameter, the edge shape viewed from above is preferably 90° or less, and more preferably 70° or less to increase the difference in wettability of the channel and the dispersed phase. By making it 90° or less, it is able to reduce a contact area between the dispersed phase and the channel near the outlet port and thereby allow the dispersed phase to disperse with a uniform particle diameter.

Particularly, by making the edge shape viewed from above 90°, it enables the dispersion with a uniform particle diameter in the combination of the dispersed phase and the channel in which a difference in wettability is small. It also allows obtaining a uniform particle diameter under the conditions where the dispersion of particles is difficult due to a high transmission pressure of the dispersed phase and a high transmission speed.

The same effects as above can be obtained also by forming a fine raised and recessed pattern on the many grooves formed on the surface of the bank. Particularly, forming the fine raised and recessed pattern on the ends of the channel can produce more effects. The fine raised and recessed pattern can also improve the efficiency of particle production. Further, the fine raised and recessed pattern on the channel can generate a flow rate change in a fluid to enhance the isolation of the particles. The number and the positions of the fine raised and recessed pattern are not restricted, and it is necessary to select them in accordance with the channel width and depth and the required efficiency of the particle production.

The efficiency of the particle production can be improved also by forming a fine raised and recessed pattern in the groove-form at the bottom of the channel. With the fine raised and recessed pattern at the bottom of the channel, when the dispersed phase passes through the channel, the air is interposed between the dispersed phase and the fine raised and recessed pattern, thereby enabling particle isolation.

As for a minimum size of the fine raised and recessed pattern to be formed, it is possible to form a fine raised and recessed pattern with the width of as small as 1 μm or less by using a scale-down exposure device called a stepper in the exposure step during the stamper manufacturing process, for example. However, since a mask used for the exposure is expensive, it is preferred to select a size considering production costs and intended uses.

Further, by placing the resin microchannel substrates on one another in the same direction and in close contact with each other to form many microchannels on a contact surface, it is able to significantly increase the efficiency of producing an emulsion with a uniform particle diameter. Lamination of 10 pieces of the resin microchannel substrates allows the efficiency increase by 10 times, and if the thickness of the substrate is 1 mm, the thickness of the lamination is as thin as 1 cm.

In order to supply a fluid as dispersed phase, a through-hole may be formed in the recess of the resin microchannel substrate. When a plurality of substrates are placed on one another, the recesses of substrates thereby become continuous with each other via the through-holes, allowing a simple structure.

If a part to be firmly attached to the surface of a substrate placed on a given side end of the plurality of substrates is a transparent plate, it is able to directly observe the channel through the transparent plate, enabling an appropriate operation.

In the case of using the resin microchannel substrates placed on one another, methods for aligning the substrates include a method of forming a raised and recessed pattern on the front and back surfaces of the substrate to place the substrates on one another with high positioning accuracy, a method of fixing the outer edges of the substrates with jigs, a method of fixing the substrates using positioning pins in the through-holes, and a method of observing and adjusting the positions using an optical device such as a CCD camera and a laser.

A step of forming a resist pattern on a substrate, a step of forming a metal structure by depositing a metal according to the resist pattern formed on the substrate, and a step of forming a resin microchannel substrate using the metal structure will be explained below.

In a resin microchannel substrate according to this embodiment, a given resist pattern is formed by performing (a) formation of the first resist layer on the substrate, (b) positioning of the substrate and a mask A, (c) exposure of the first resist layer using the mask A , (d) heat-treatment of the first resist layer, (e) formation of the second resist layer on the first resist layer, (f) positioning of the substrate and the mask B, (g) exposure of the second resist layer using the mask B, (h) heat-treatment of the second resist layer, and (i) development of the resist layers.

Further, according to the resist pattern thus formed, a metal structure is deposited on the substrate by plating. By forming a resin molded product using the metal structure as a mold, a resin microchannel substrate is produced.

The resist pattern formation step will be explained in further detail below. To form a micro groove with the depth of 20 μm and a recess with the depth of 80 μm on a substrate, for example, the first resist layer (80 μm in thickness) is deposited and the second resist layer (20 μm in thickness) is deposited thereon, and each layer is exposed or exposed and heat-treated.

In the development process, a pattern with the depth of 20 μm, which is the second resist layer, is first obtained. Then, a pattern with the depth of 80 μm, which is the thickness of the first resist layer plus the thickness of the second resist layer, is obtained. In order to prevent the 20 μm pattern of the second resist layer from being dissolved or distorted by a developer when forming the 80 μm pattern, it is required to control the solubility of each layer in the developer. In the case of forming the resist layer by spin coating, it is possible to develop alkali resistance by adjusting a baking (solvent drying) time of the second resist layer.

One technique for developing the alkali resistance of photodegradable positive resist is to increase a baking time (solvent drying time) so as to harden the resist. The baking time of the resist is normally adjusted according to the thickness of layer, the density of solvent such as thinner, and the sensitivity. Increasing the baking time can develop the alkali resistance.

Overbaking of the first resist layer hardens the resist too much, making it difficult to dissolve an exposed part and form a pattern in the subsequent development step. Thus, it is preferred to adjust baking conditions by reducing the baking time and so on. Equipment used for the baking is not particularly limited as long as it can dry a solvent, including an oven, a hot plate, a hot-air dryer, and so on.

Since the development of the alkali resistance of the photodegradable positive resist and chemical amplification positive resist is limited compared to photocrosslinkable negative resist, the combined thickness of each resist layer is preferably 5 to 200 μm, and more preferably, 10 to 100 μm. Besides the optimization of the baking time, another method for developing the alkali resistance of the photocrosslinkable negative resist is optimization of crosslink density. Normally, the crosslink density of the negative resist can be adjusted by the exposure amount. In the case of chemical amplification resist, it can be adjusted by the exposure amount and the heat-treatment time. The alkali resistance can be developed by increasing the exposure amount or the heat-treatment time. When using the photocrosslinkable negative resist, the combined thickness of each resist layer is preferably 5 to 500 μm, and more preferably, 10 to 300 μm.

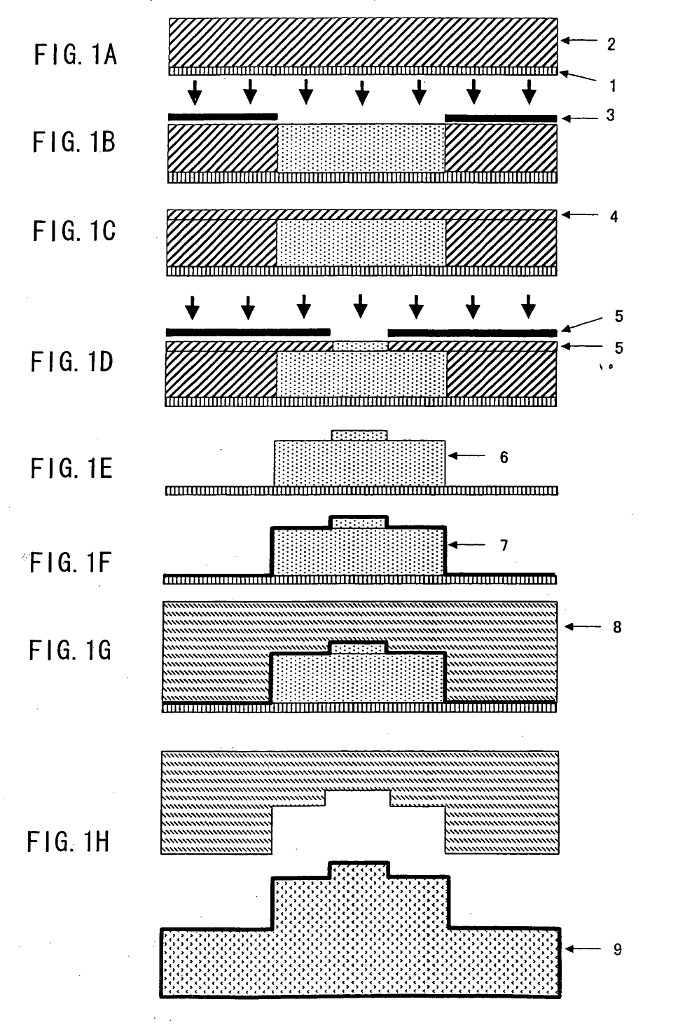

(a) The formation of the first resist layer 2 on the substrate 1 will be explained below. FIG. 1A shows the first resist layer 2 formed on the substrate 1. The flatness of a cell culture plate, which is an example of the resin molded product obtained by the molded product formation step, is determined by the step of forming the first resist layer 2 on the substrate 1. Thus, the flatness when the first resist layer 2 is deposited on the substrate 1 is reflected in the flatness of the metal structure and the cell culture plate eventually.

Though a technique to form the first resist layer 2 on the substrate 1 is not limited in any way, spin coating, dip coating, roll coating, and dry film resist lamination are generally used. Particularly, the spin coating is a technique to deposit resist on a spinning glass substrate and it has an advantage of very flat coating of resist on a glass substrate with the diameter of more than 300 mm in diameter. The spin coating is thus preferred for use to achieve high flatness.

There are two types of resist that may be used as the first resist layer 2: positive resist and negative resist. Since the depth of focus on the resist changes depending on the resist sensitivity and exposure conditions, when using a UV exposure system, for example, it is preferred to select an exposure time and a UV output level according to the type, thickness, and sensitivity of the resist. If the resist used is wet resist, to obtain a given resist thickness by the spin coating, for example, a technique of changing the spin coating rotation speed or a technique of adjusting the viscosity may be used.

The technique of changing the spin coating rotation speed obtains a given resist thickness by setting the rotation speed of a spin coater. The method of adjusting the viscosity adjusts the resist viscosity according to the flatness level required for practical use since the degradation of flatness can occur if the resist is thick or the resist deposition area is large.

In the spin coating technique, for example, the thickness of the resist layer deposited at a time is preferably 10 to 50 μm, more preferably 20 to 50 μm, to maintain high flatness. In order to obtain a given resist layer thickness while retaining high flatness, a plurality of resist layers may be formed.

When photodegradable positive resist is used for the first resist layer 2, if a baking time (solvent drying) is too long, the resist hardens too much, making it difficult to form a pattern in the subsequent development step. Thus, it is preferred to select baking conditions by reducing the baking time and so on if the resist thickness is less than 100 μm.

(b) The positioning of the substrate 1 and the mask A 3 will be explained below. For a given positional relationship between the pattern of the first resist layer and the pattern of the second resist layer, accurate positioning is necessary in the exposure using the mask A 3. Positioning methods include a method of providing cutting in the corresponding positions of the substrate 1 and the mask A 3 and fixing them with pins, a method of reading the positions by laser interferometry, and a method of creating position marks in the corresponding positions of the substrate 1 and the mask A 3 and performing positioning with an optical microscope.

In the method of performing positioning with an optical microscope, a position mark is created on the substrate by photolithography technique and created on the mask A 3 by laser beam equipment, for example. This method is effective in that the accuracy within 5 μm can be easily obtained by manual operation using the optical microscope.

(c) The exposure of the first resist layer 2 with the mask A 3 will be explained below. The mask A 3 used in the step shown in FIG. 1B is not limited in any way. An emulsion mask, a chrome mask, and so on may be used. In the resist pattern formation step, the size and accuracy depends on the mask A used. The size and accuracy are reflected in the resin molded product. Hence, to obtain a nano/micro structure cell culture plate with a given size and accuracy, it is necessary to specify the size and accuracy of the mask A. A technique to increase the accuracy of the mask A 3 is not limited in any way. For example, one technique is to change a laser used for the pattern formation of the mask A 3 to the one with the shorter wavelength. This technique, however, requires high facility costs, resulting in higher fabrication costs of the mask A 3. It is thus preferred to specify the mask accuracy according to the accuracy level required for practical use of the nano/micro structure cell culture plate.

The material of the mask A 3 is preferably quartz glass in terms of temperature expansion coefficient and UV light transmission and absorption characteristics; however, since it is relatively expensive, the material is preferably selected according to the accuracy level required for practical use of the resin molded product.

In order to obtain a given structure with different depths or heights or a structure in which the first resist pattern and the second resist pattern are different, it is necessary to ensure the design of the patterns (transmitting/shielding parts) of the masks used for the exposure of the first resist layer 2 and the second resist layer 4. An approach to achieve this is to perform simulation using CAE analysis software.

The light used for the exposure is preferably ultraviolet light or laser light for low facility costs. The exposure light may be the synchrotron radiation. Though the synchrotron radiation makes deep exposure, it requires high facility costs and thus substantially increases the price of the the nano/micro structure cell culture plate.

Since exposure conditions such as exposure time and intensity vary by material, thickness, and so on of the first resist layer 2, they are preferably adjusted according to the pattern to be formed. The adjustment of the exposure conditions is important since it affects the accuracy and the sizes of a pattern such as the width and height of a flow channel, and the interval, width (or diameter), and height of a reservoir. Further, since the depth of focus changes depending on the resist type, when using the UV exposure system, for example, it is preferred to select an exposure time and a UV output level according to the thickness and sensitivity of the resist.

(d) The heat-treatment of the first resist layer 2 will be explained below. Annealing is known as a heat-treatment after the exposure to correct the shape of the resist pattern. Here, it aims at chemical crosslinking and is used only when the chemical amplification negative resist is used. The chemical amplification negative resist mainly comprises two- or three-component system. For example, the terminal epoxy group of a chemical structure is ring-opened by exposure light and crosslinking reaction starts by the heat-treatment. If the layer thickness is 100 μm, the crosslinking reaction progresses in several minutes by the heat-treatment with the temperature of 100° C.

Excessive heat-treatment of the first resist layer 2 makes it difficult to dissolve a non-crosslinked part to form a pattern in the subsequent development step. Thus, if the resist thickness is less than 100 μm, it is preferred to adjust the operation by reducing the heat-treatment time, performing the heat-treatment only on the second resist layer 4 formed later, and so on.

(e) The formation of the second resist layer 4 on the first resist layer 2 will be explained below. FIG. 1C shows the state where the second resist layer 4 is formed. The second resist layer 4 may be formed by the same process as the formation of the first resist layer 2 explained in the step (a).

In the case of forming a resist layer using positive resist by the spin coating, increasing the baking time about 1.5 to 2 times longer than usual enables development of the alkali resistance. It is thereby possible to prevent the dissolution or distortion of the resist pattern of the second resist layer 4 at the completion of the development of the first resist layer 2 and the second resist layer 4.

(f) The positioning of the substrate 1 and the mask B 5 will be explained below. The positioning of the substrate 1 and the mask B 5 is performed in the same manner as the positioning of the substrate 1 and the mask A 3 explained in the step (b).

(g) The exposure of the second resist layer 4 with the mask B 5 will be explained below. The exposure of the second resist layer 4 with the mask B 5 is performed in the same manner as the exposure of the first resist layer 2 with the mask A 3 explained in the step (c). FIG. 1D shows the exposure of the second resist layer 4.

(h) The heat-treatment of the second resist layer 4 will be explained below. The heat-treatment of the second resist layer 4 is basically the same as the heat-treatment of the first resist layer 2 explained in the above step (d). The heat-treatment of the second resist layer 4 is performed in order to avoid the dissolution or distortion of the pattern of the second resist layer 4 when the pattern of the first resist layer 2 is formed in the subsequent development step. The heat-treatment enhances the chemical crosslinking to increase the crosslink density, thereby developing the alkali resistance. The heat-treatment time for developing the alkali resistance is preferably selected according to the resist thickness from the range of 1.1 to 2.0 times longer than usual.

(i) The development of the resist layers 2 and 4 will be explained below. The development in the step shown in FIG. 1E preferably uses a given developer suitable for the resist used. It is preferred to adjust development conditions such as development time, development temperature, and developer density according to the resist thickness and pattern shape. Setting appropriate conditions is preferred since overlong development time causes the pattern to be larger than a given size, for example.

As the entire thickness of the resist layers 2 and 4 increases, the width (or diameter) of the top surface of the resist may become undesirably larger than that of the bottom of the resist in the development step. Thus, when forming a plurality of resist layers, it is preferred in some cases to form different resist with different sensitivity in each resist layer formation step. In this case, the sensitivity of the resist layer close to the top is set higher than that of the resist layer close to the bottom. Specifically, BMR C-1000PM manufactured by TOKYO OHKA KOGYO CO., LTD. may be used as the higher sensitivity resist and PMER-N-CA3000PM manufactured by TOKYO OHKA KOGYO CO., LTD. may be used as the lower, sensitivity resist. It is also possible to adjust the sensitivity by changing the drying time of the resist. For example, in the case of using BMR C-1000PM manufactured by TOKYO OHKA KOGYO CO., LTD., drying of the first resist layer for 40 minutes at 110° C. and the second resist layer for 20 minutes at 110° C. in a resist drying operation after the spin coating allows the first resist layer to have the higher sensitivity.

Methods to increase the flatness accuracy of the top surface of the molded product or the bottom of the micropattern include a method of changing the type of resist (negative or positive) used in the resist coating to apply the flatness of the glass surface and a method of polishing the surface of a metal structure.

In the case of forming a plurality of resist layers to obtain a given pattern depth, it is possible to perform the exposure and development of the plurality of resist layers at the same time. It is also possible to form and expose one resist layer and further forms and exposes another resist layer, and then perform the development of the two resist layers at the same time.

The metal structure formation step will be explained in further detail. The metal structure formation step deposits a metal over the resist pattern formed by the resist pattern formation step to form an uneven surface of a metal structure in accordance with the resist pattern, thereby obtaining the metal structure.

This step first deposits a conductive layer 7 in accordance with the resist pattern as shown in FIG. 1F. Though a technique of forming the conductive layer 7 is not particularly limited, it is preferred to use vapor deposition, sputtering, and so on. A conductive material used for the conductive layer 7 may be gold, silver, platinum, copper, and aluminum, for example.

After forming the conductive layer 7, a metal is deposited in accordance with the pattern by plating, thereby forming the metal structure 8 as shown in FIG. 1G. A plating method for depositing the metal is not particularly limited, and electroplating or electroless plating may be used, for example. A metal used is not particularly limited, and nickel, nickel and cobalt alloy, copper, or gold may be used, for example. Nickel is preferred since it is durable and less costly.

The metal structure 8 may be polished depending on its surface condition. In this case, to prevent contaminations from attaching to a product, it is preferred to perform ultrasonic cleaning after the polishing. Further, it is also possible to perform surface treatment of the metal structure 8 with mold release agent and the like so as to improve the surface condition. The angle of gradient along the depth direction of the metal structure 8 is preferably 50° to 90°, and more preferably, 60° to 87°. The metal structure 8 deposited by plating is then separated from the resist pattern.

The molded product formation step will be explained hereinafter in further detail. The molded product formation step uses the metal structure 8 as a mold to form a resin molded product 9 as shown in FIG. 1H.

Though a technique to form the resin molded product 9 is not particularly limited, injection molding, press molding, monomer casting, solution casting, or roll transfer by extrusion molding may be used, for example. The injection molding is preferred for its high productivity and pattern reproducibility. If the resin molded product 9 is formed by the injection molding using the metal structure 8 with a given size as a mold, it is able to reproduce the shape of the metal structure 8 to the resin molded product 9 with a high reproduction rate. The reproduction rate may be determined by using an optical microscope, a scanning electron microscope (SEM), a transmission electron microscope (TEM), and so on.

In the case of producing the resin molded product 9 using the metal structure 8 as a mold by the injection molding, for example, 10,000 to 50,000 pieces or even 200,000 pieces of resin molded products may be obtained with one metal structure 8. It is thus possible to largely eliminate the costs for producing the metal structures 8. Besides, one cycle of the injection molding takes only 5 to 30 seconds, being highly productive.

The productivity further increases with the use of a mold capable of simultaneous production of a plurality of resin molded products in one injection molding cycle. In this molding process, the metal structure 8 may be used as a metal mold; alternatively, the metal structure 8 may be placed inside a prepared metal mold.

A resin material used for the formation of the resin molded product 9 is not particularly limited. Acrylic resin, polylactide resin, polyglycolic acid resin, styrene resin, acrylic-styrene copolymer (MS resin), polycarbonate resin, polyester resin such as polyethylene terephthalate, polyvinyl alcohol resin, ethylene-vinyl alcohol copolymer, thermoplastic elastomer such as styrene elastomer, vinyl chloride resin, or silicone resin such as polydimethylsiloxane may be used, for example.

The above resin may contain one or more than one agent of lubricant, light stabilizer, heat stabilizer, antifogging agent, pigment, flame retardant, antistatic agent, mold release agent, antiblocking agent, ultraviolet absorbent, antioxidant, and so on.

The minimum value of the flatness of the resin molded product 9 is preferably 1 μm to enable easy industrial reproduction. The maximum value of the flatness of the resin molded product 9 is preferably 200 μm in order not to cause a problem in the attachment of the molded product 9 to another substrate. The dimensional accuracy of the pattern of the resin molded product 9 is preferably within the range of ±0.5 to 10% to enable easy industrial reproduction.

The dimensional accuracy of the thickness of the resin molded product 9 is preferably within the range of +0.5 to 10% to enable easy industrial reproduction. The thickness of the resin molded product 9 is not particularly specified, but it is preferably within the range of 0.2 to 10 mm to prevent breakage at removal in the injection molding, or breakage, deformation, or distortion during operation. The size of the resin molded product 9 is also not particularly specified, and it is preferably selected according to usage. For example, when forming the resist pattern by the lithography technique, if the resist layer is formed by spin coating, the diameter is preferably within 400 mm in diameter.

### EXAMPLES

A method of producing a resin microchannel substrate according to the present invention will be explained hereinafter in further detail with reference to the drawings. Though the present invention will be explained in detail based on examples, it is not limited to these examples.

A method of producing a resin molded product according to the present invention will be explained with reference to the drawings. Referring first to FIG. 1A, the first resist coating on a substrate was performed using an organic material (PMER N-CA3000PM manufactured by TOKYO OHKA KOGYO CO., LTD.).

Referring next to FIG. 1B, after the first resist layer formation, positioning of the substrate and a mask A having a given mask pattern was performed. After that, the first resist layer was exposed to UV light by a UV exposure system (PLA-501F manufactured by CANON INC. with the wavelength of 365 nm and the exposure dose of 300 mJ/cm2). The first resist layer was then heat-treated using a hot plate at 100° C. for 4 minutes. Referring then to FIG. 1C, the second resist coating on the substrate was performed using an organic material (PMER N-CA3000PM manufactured by TOKYO OHKA KOGYO CO., LTD.).

Referring then to FIG. 1D, after the second resist layer formation, positioning of the substrate and a mask B with a given mask pattern was performed.

After that, the second resist layer was exposed to UV light by a UV exposure system (PLA-501F manufactured by CANON INC. with the wavelength of 365 nm and the exposure dose of 100 mJ/cm2). The second resist layer was then heat-treated using a hot plate at 100° C. for 8 minutes. Referring then to FIG. 1E, development was performed on the substrate having the resist layers, thereby forming a resist pattern on the substrate (developer: PMER developer P-7G manufactured by TOKYO OHKA KOGYO CO., LTD.)

Referring now to FIG. 1F, vapor deposition or sputtering was performed on the substrate with the resist pattern, thereby depositing a conductive layer formed of silver on the surface of the resist pattern. Instead of the silver, platinum, gold, copper, or the like may be deposited in this step.

Referring then to FIG. 1G, the substrate having the resist pattern was immersed in a plating solution for electroplating to form a metal structure (hereinafter referred to as a Nickel structure) in gaps in the resist pattern. Instead, copper, gold, or the like may be deposited in this step.

Referring finally to FIG. 1H, a plastic material was filled in the Ni structure using the Nickel structure as a mold by injection molding. A plastic molded product was thereby produced. A material used for the injection molding was PARAPET GH-S, acryl manufactured by KURARAY, CO. LTD.

[Manufacture of Resin Substrate A]

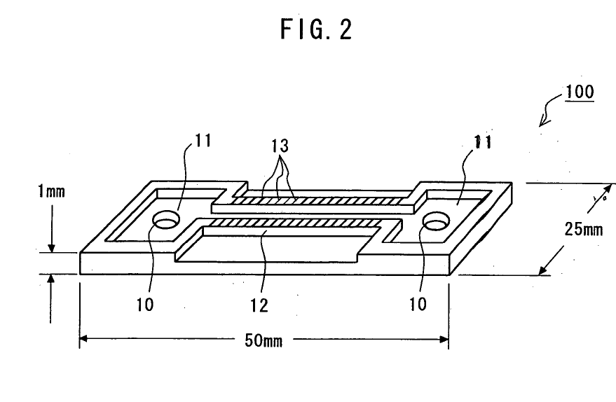

According to the molded product production process shown in FIGS. 1A to 1H, the resist coating was repeated twice to form the first resist layer and then exposure and heat-treatment were performed on each layer. Further, the resist coating was performed once again to form the second resist layer, and then the exposure and the heat-treatment were performed thereon. A resin microchannel substrate 100, as shown in FIG. 2, having a substrate with 50 mm in width, 25 mm in length, and 1.0 mm in thickness on which a micro groove 13 with 20 μm in width and 10 μm in depth and a recess 11 with 80 μm in depth were formed was thereby manufactured. The edge angle of the channel was 90°. A through-hole 10 to serve as a fluid supply port was created in the recess 11.

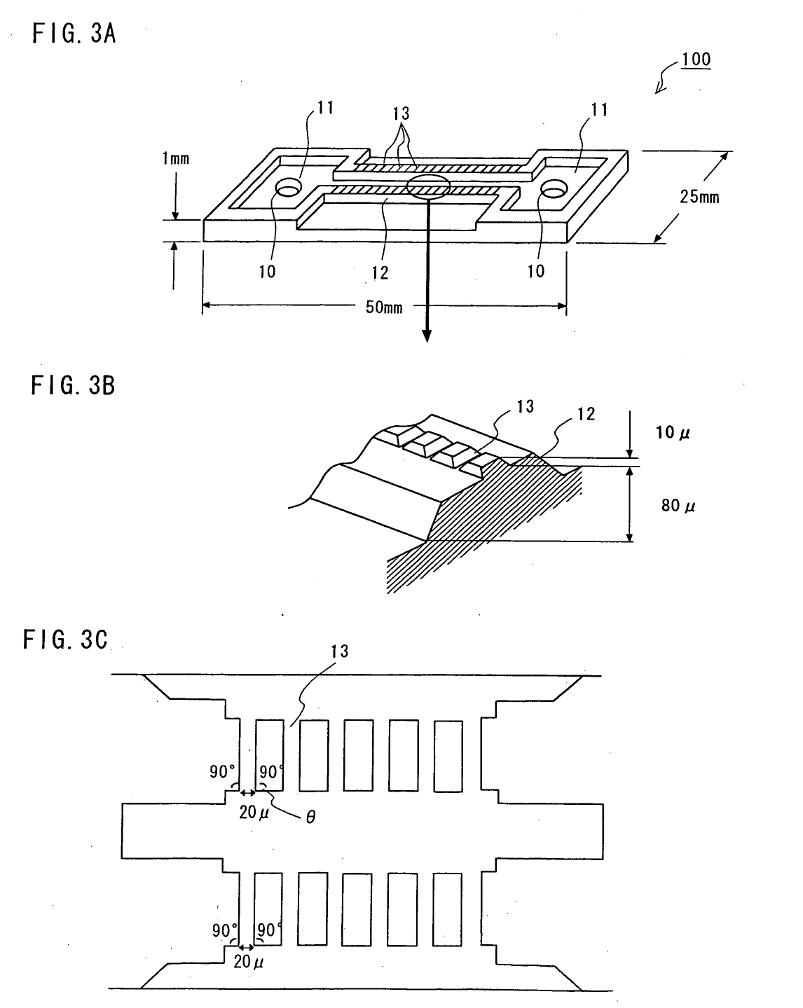

The contact angle with respect to water was measured in the air. The measurement with a contact angle measurement device (CA-DT/A manufactured by KYOWA INTERFACE SCIENCE CO., LTD.) resulted in 70°. The structure of the groove 13 formed on the bank 12 is shown in FIGS. 3A to 3C.

[Manufacture of Resin Substrate B]

According to the molded product production process shown in FIGS. 1A to 1H, the resist coating was repeated twice to form the first resist layer and then exposure and heat-treatment were performed on each layer. Further, the resist coating was performed once again to form the second resist layer, and then the exposure and the heat-treatment were performed thereon. A resin microchannel substrate 100, as shown in FIG. 2, having a substrate with 50 mm in width, 25 mm in length, and 1.0 mm in thickness on which a micro groove 13 with 20 μm in width and 10 μm in depth and a recess 11 with 80 μm in depth were formed was thereby manufactured. A channel was formed by the groove 13. The edge angle of the channel was 90°. A through-hole 10 to serve as a fluid supply port was created in the recess 11.

Surface modification by ultraviolet irradiation was performed on the microchannel substrate and the acrylic flat plate. An excimer light (172 nm) irradiation device (UER manufactured by USHIO INC.) was used for the irradiation of ultraviolet light for 60 seconds. Then, the contact angle with respect to water was measured as is the case with the resin substrate 1, which resulted in 19°.

The structure of the groove 13 formed on the bank 12 is shown in FIGS. 3A to 3C. FIG. 3A is a perspective view of the microchannel substrate 1, FIG. 3B is an enlarged perspective view of the groove 13 and its vicinity, and FIG. 3C is an enlarged top view of the groove 13 and its vicinity.

[Manufacture of Resin Substrate C]

According to the molded product production process shown in FIGS. 1A to 1H, the resist coating was repeated twice to form the first resist layer and then exposure and heat-treatment were performed on each layer. Further, the resist coating was performed once again to form the second resist layer, and then the exposure and the heat-treatment were performed thereon. A resin microchannel substrate 100, as shown in FIG. 2, having a substrate with 50 mm in width, 25 mm in length, and 1.0 mm in thickness on which a micro groove 13 with 20 μm in width and 10 μm in depth and a recess 11 with 80 μm in depth were formed was thereby manufactured. The edge angle of the channel was set to 65° in order to improve the efficiency of particle production and suppress the variation in particle diameter.

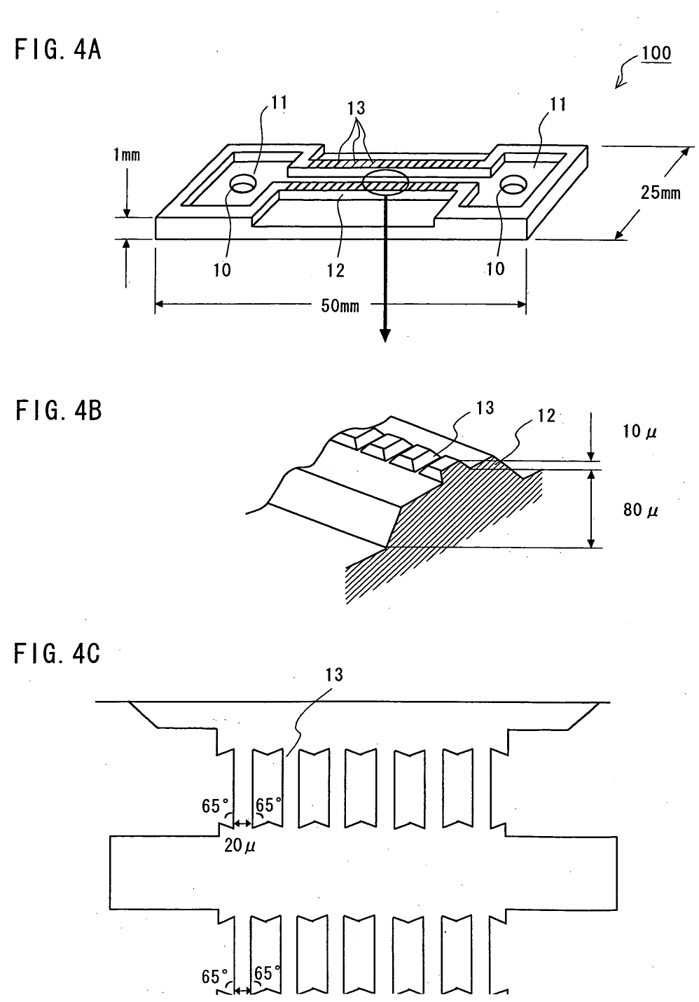

Then, as with the resin substrate 1, the ultraviolet irradiation was performed for 60 seconds. The contact angle with respect to water was 20°. The structure of the groove 13 formed on the bank 12 is shown in FIGS. 4A to 4C. FIG. 4A is a perspective view of the microchannel substrate 1, FIG. 4B is an enlarged perspective view of the groove 13 and its vicinity, and FIG. 4 is an enlarged top view of the groove 13 and its vicinity.

[Manufacture of Resin Substrate D]

According to the molded product production process shown in FIGS. 1A to 1H, the resist coating was repeated twice to form the first resist layer and then exposure and heat-treatment were performed on each layer. Further, the resist coating was performed once again to form the second resist layer, and then the exposure and the heat-treatment were performed thereon. A resin microchannel substrate 100, as shown in FIG. 2, having a substrate with 50 mm in width, 25 mm in length, and 1.0 mm in thickness on which a micro groove 13 with 10 μm in width and 5 μm in depth and a recess 11 with 60 μm in depth were formed was thereby manufactured. The edge angle of the channel was set to 90°.

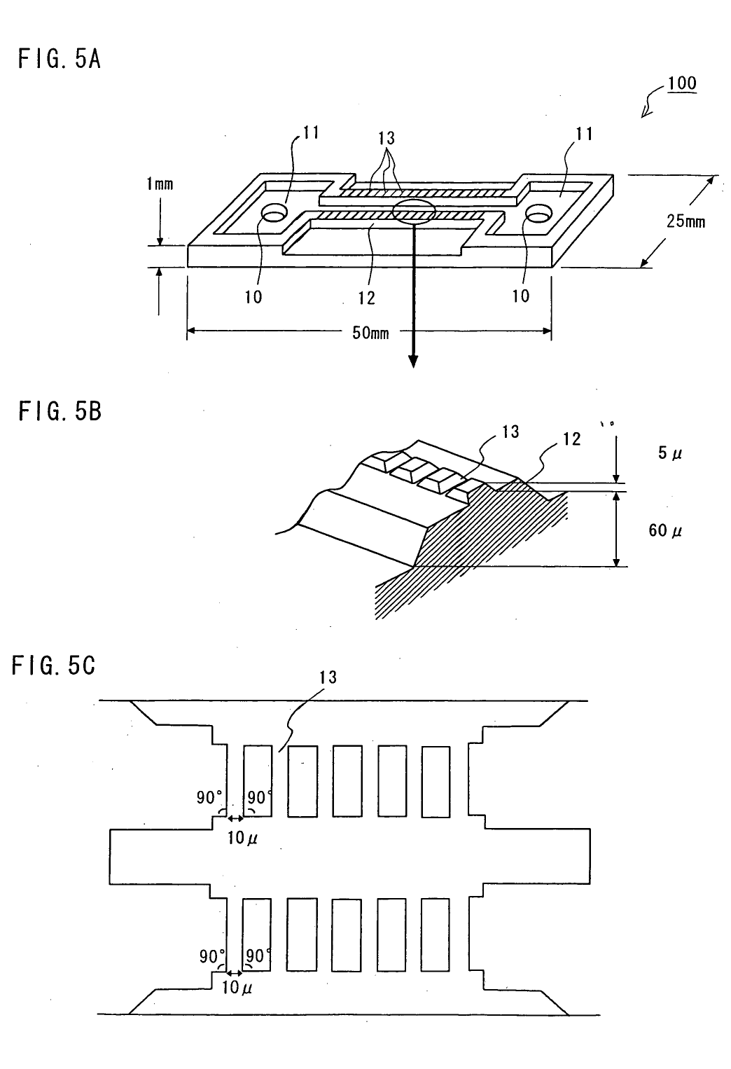

Surface modification by plasma treatment was performed on the microchannel substrate and the acrylic flat plate thus manufactured. Using a sputtering device (SV, manufactured by ULVAC, INC.), 1000 Å of SiO2 layer was deposited. The contact angle with respect to water was 16°. The structure of the groove 13 formed on the bank 12 is shown in FIGS. 5A to 5C. FIG. 5A is a perspective view of the microchannel substrate 1, FIG. 5B is an enlarged perspective view of the groove 13 and its vicinity, and FIG. 5C is an enlarged top view of the groove 13 and its vicinity.

[Manufacture of Resin Substrate E]

According to the molded product production process shown in FIGS. 1A to 1H, the resist coating was repeated three times to form the first resist layer and then exposure and heat-treatment were performed on each layer. Further, the resist coating was performed once again to form the second resist layer, and then the exposure and the heat-treatment were performed thereon. A resin microchannel substrate 100, as shown in FIG. 2, having a substrate with 50 mm in width, 25 mm in length, and 1.0 mm in thickness on which a micro groove 13 with 40 μm in width and 20 μm in depth and a recess 11 with 100 μm in depth were formed was thereby manufactured. In the edge of the channel, a raised pattern of 40 μm in width and 20 μm in length was formed in order to improve the efficiency of particle production and suppress the variation in particle diameter.

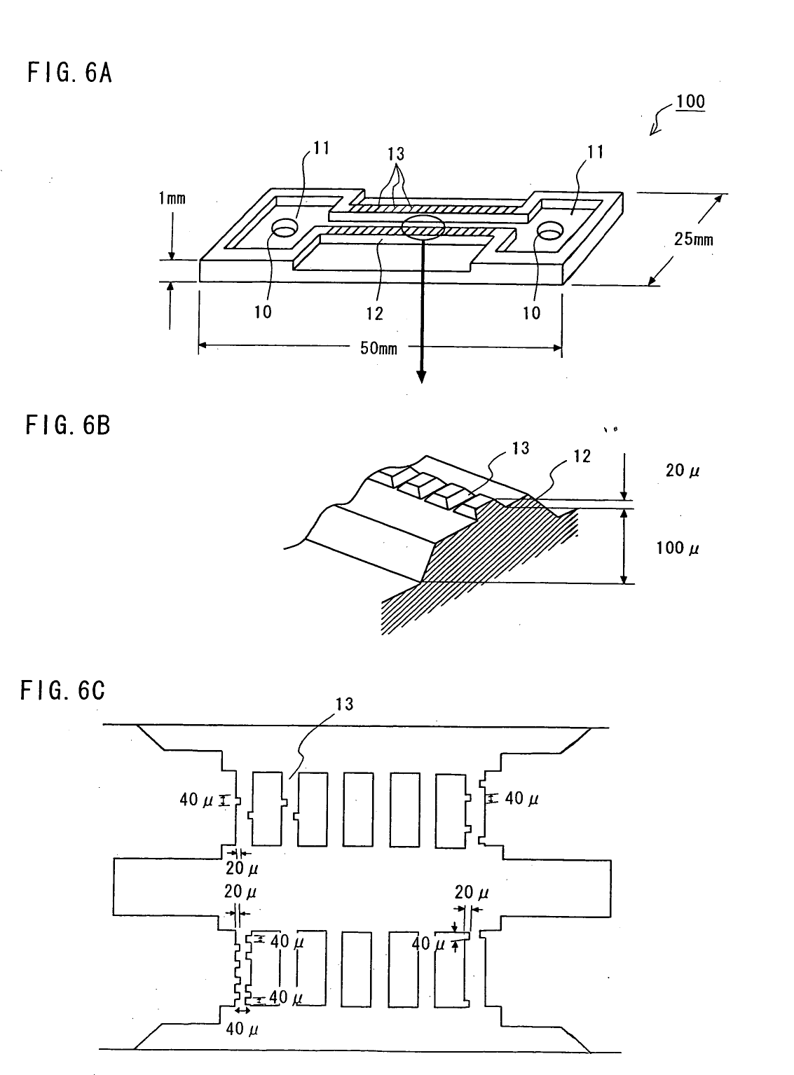

As with the resin substrate D, the surface modification by plasma treatment was performed. Using the sputtering device (SV, manufactured by ULVAC, INC.), 1000 Å of SiO2 layer was deposited. The contact angle with respect to water was 18°. The structure of the groove 13 formed on the bank 12 is shown in FIGS. 6A to 6C. FIG. 6A is a perspective view of the microchannel substrate 1, FIG. 6B is an enlarged perspective view of the groove 13 and its vicinity, and FIG. 6C is an enlarged top view of the groove 13 and its vicinity.

### Example 1

### Production of Monodispersed Water-In-Oil Microparticles Using Resin Substrate A

A production test of monodispersed water-in-oil microparticles was performed using pure water as dispersed phase (water) and triolein as continuous phase (oil). Since the contact angle with respect to water was as high as 70°, it was able to obtain an emulsion having uniform water particles without wetting of the pure water as water and the substrate at the outlet port of a fluid channel.

The particle diameter was measured using a particle diameter measurement device (PAR-III manufactured by OTSUKA ELECTRONICS CO., LTD.). The result was an average particle diameter of 48. 5 μm and a coefficient of variation of 3.5%, showing that it is possible to produce the emulsion with very uniform particles.

### Example 2

### Production of Monodispersed Oil-In-Water Microparticles Using Resin Substrate B

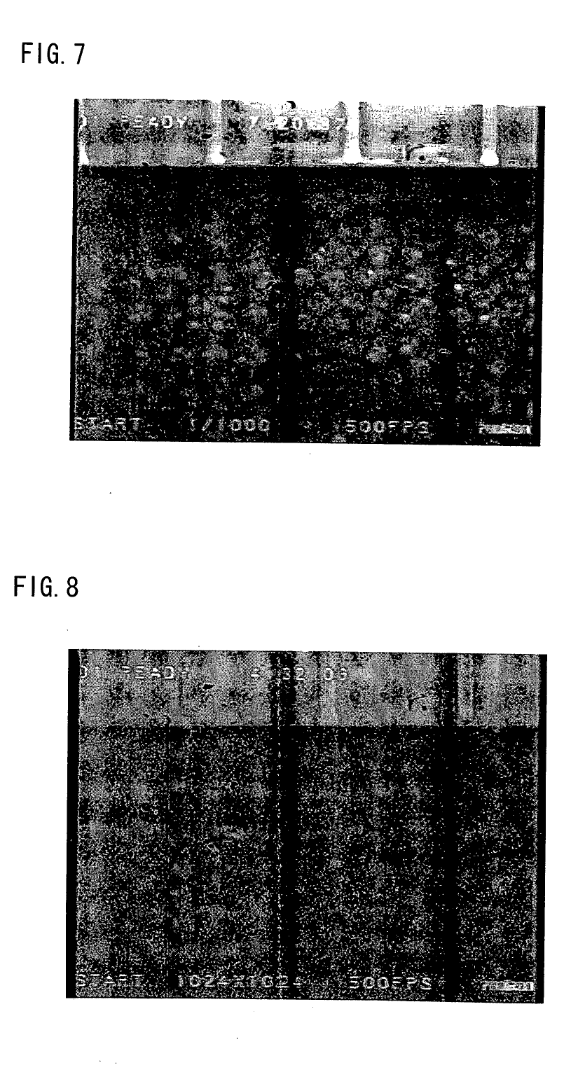

A production test of monodispersed oil-in-water microparticles was performed using triolein as dispersed phase (oil) and pure water as continuous phase (water). Since the contact angle with respect to water is as low as 19°, it was able to obtain an emulsion having uniform triolein particles without wetting of the triolein as oil and the substrate at the outlet port of a channel. The particle diameter was measured using a particle diameter measurement device (PAR-III manufactured by OTSUKA ELECTRONICS CO., LTD.). The result was an average particle diameter of 45.5 μm and a coefficient of variation of 3.0%, showing that it is possible to produce the emulsion with very uniform particles. An image observed optically with a CCD camera is shown in FIG. 7.

### Example 3

### Production of Monodispersed Oil-In-Water Microparticles Using Resin Substrate C

As with the production of monodispersed oil-in-water microparticles using the resin substrate 1, it was able to obtain an emulsion having uniform triolein particles. This example sets the edge angle to 65°, and an average particle diameter was 41.0 μm and a coefficient of variation was 1.5%, showing that it is possible to produce the emulsion with more uniform particles. Further, under the condition where the transmission speed of the triolein as dispersed phase was changed from 10 ml/h to 30 ml/h, it was able to produce the monodispersed microparticle by setting the edge angle to 65°. An image observed optically with a CCD camera is shown in FIG. 8.

### Example 4

### Production of Monodispersed Oil-In-Water Microparticles Using Resin Substrate D

As with the production of monodispersed oil-in-water microparticles using the resin substrate 2, it was able to obtain an emulsion having uniform triolein particles. An average particle diameter was 18.6 μm and a coefficient of variation was 2.4%, showing that it is possible to produce the emulsion with uniform particles.

### Example 5

### Production of Monodispersed Oil-In-Water Microparticles Using Resin Substrate E

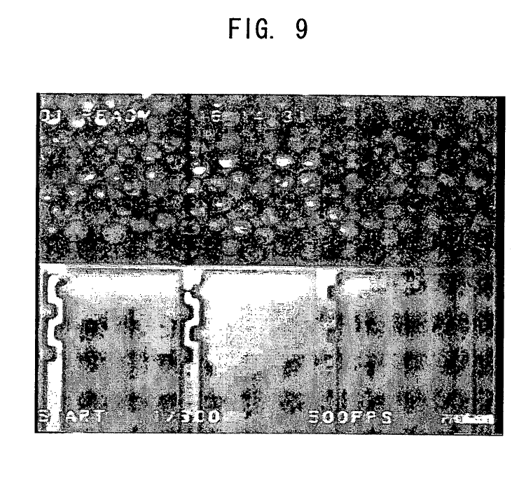

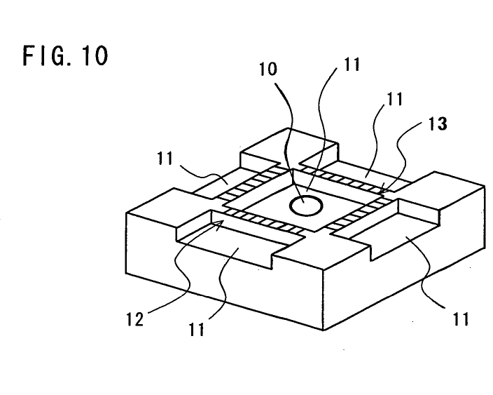

As with the production of monodispersed oil-in-water microparticles using the resin substrate 2, it was able to obtain an emulsion having uniform triolein particles. An average particle diameter was 78.2 μm and a coefficient of variation was 3.8%, showing that it is possible to produce the emulsion with uniform particles. An image observed optically with a CCD camera is shown in FIG. 9.

### Comparative Example

### Production of Monodispersed Oil-In-Water Microparticles Using Resin Substrate 1

A production test of monodispersed oil-in-water microparticles was performed using triolein as dispersed phase (oil) and pure water as continuous phase (water). In this test, an acrylic flat plate as a cover was firmly attached to the resin substrate 1 so as to form a microchannel. Since the contact angle with respect to water was as high as 70°, this example resulted in the wetting of the triolein as oil and the substrate at the outlet port of the channel. Thus, the triolein particle did not isolate and it was unable to obtain the uniform emulsion.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

1. A resin microchannel substrate comprising:
a surface having a recess leading to a fluid supply port and a bank adjacent to the recess and having many micro grooves on a surface, which grooves form microchannels connecting an inside of the recess and an outside of the recess when the surface of the substrate is firmly attached to a flat plate serving as a cover,
wherein each of width and height of the microchannels is within a range of 1 to 300 μm and a width/height ratio of the microchannels is within a range of 1:20 to 20:1.

2. A resin microchannel substrate according to claim 1, wherein a contact angle of the surface of the resin microchannel substrate with respect to water is 5° to 60°.

3. A resin microchannel substrate according to claim 1, wherein an edge angle of the many grooves on the surface of the bank is 90° or less.

4. A resin microchannel substrate according to claim 1, wherein the many grooves on the surface of the bank have a fine raised and recessed structure.

5. A resin microchannel substrate according to claim 1, wherein the resin microchannel substrate is a laminated resin microchannel substrate comprising a plurality of substrates placed on one another in the same direction and in close contact with each other to form many microchannels on a contact surface.

6. A resin microchannel substrate according to claim 5, comprising a substrate alignment unit used when placing the resin microchannel substrates on one another.

7. A method of manufacturing a resin microchannel substrate of claim 1, comprising the steps of:
forming a resist pattern on a substrate;
forming a metal structure by depositing a metal according to the resist pattern formed on the substrate; and
forming a resin microchannel substrate by using the metal structure.

8. A filtration and classification method using a resin microchannel substrate of claim 1, wherein particles are separated by running a particle floating fluid through the microchannels.

9. A filtration and classification method using a resin microchannel substrate according to claim 8, wherein a part to be firmly attached to the surface of the substrate having many grooves is a transparent plate so as to perform filtration and classification while optically observing a separation process in at least part of the many microchannels.

10. A method of producing an emulsion using a resin microchannel substrate of claim 1, wherein a first fluid is sent from the inside of the recess to the outside of the recess through the microchannels and dispersed in a second fluid supplied to the outside of the recess and not mixing with the first fluid.

11. A method of producing an emulsion according to claim 10, wherein a part to be firmly attached to the surface of the substrate having many grooves is a transparent plate in at least part of the many microchannels.
